(19) United States
(12) Patent Application Publication
(10) Pub. No.: US 2023/0369328 A1
(43) Pub. Date: Nov. 16, 2023

(54) SEMICONDUCTOR STRUCTURE AND METHOD FOR FORMING SAME

(71) Applicant: Semiconductor Manufacturing International (Shanghai) Corporation, Shanghai (CN)

(72) Inventors: Bo SU, Shanghai (CN); Abraham YOO, Shanghai (CN); Hansu OH, Shanghai (CN); Byung Sup SHIM, Shanghai (CN)

(73) Assignee: Semiconductor Manufacturing International (Shanghai) Corporation, Shanghai (CN)

(21) Appl. No.: 18/127,736

(22) Filed: Mar. 29, 2023

(30) Foreign Application Priority Data
May 16, 2022 (CN) 202210528457.4

(51) Int. Cl. H01L 27/092; H01L 29/06; H01L 29/423; H01L 29/775; H01L 21/8238; H01L 29/66

(52) U.S. Cl. CPC H01L 27/092; H01L 29/0673; H01L 29/42392; H01L 29/775; H01L 21/823807; H01L 21/823814; H01L 29/66439; H01L 29/66545

(57) ABSTRACT

A semiconductor structure and a method for forming the same are provided. The method includes: removing a partial thickness of a first channel layer in an N-type region along a direction parallel to the substrate, to form a first trench, where the first trench is defined by the remaining first channel layer and an adjacent sacrificial layer or by the remaining first channel layer and the adjacent sacrificial layer and a limiting layer; filling the first trench with a sidewall channel film; removing the remaining first channel layer in the N-type region, so that a second trench is defined between the sidewall channel film and the adjacent sacrificial layer or between the sidewall channel film and the adjacent sacrificial layer and the limiting layer; and filling the second trench with a center channel film, where the center channel film and the sidewall channel film are in contact with each other to form a second channel layer, and the second channel layer is configured to improve carrier mobility in a channel of an NMOS transistor. Embodiments of the present disclosure improve performance of a semiconductor structure.

### RELATED APPLICATIONS

The present application claims priority to Chinese Patent Appln. No. 202210528457.4, filed May 16, 2022, the entire disclosure of which is hereby incorporated by reference.

### TECHNICAL FIELD

Embodiments and implementations of the present disclosure relate to the field of semiconductor manufacturing, and in particular, to a semiconductor structure and a method for forming the same.

### BACKGROUND

With the rapid development of semiconductor manufacturing technologies, semiconductor devices develop toward a higher element density and a higher integration level, and there is a decreasing trend for semiconductor process nodes to follow the Moore's Law. Transistors are currently being widely used as the most basic semiconductor devices. Therefore, as the element density and the integration level of the semiconductor devices increase, channel lengths of the transistors need to be continuously shortened to adapt to reduced process nodes.

In order to better meet the requirement of proportional reduction in a device size, the semiconductor process gradually transits from a planar transistor to a three-dimensional transistor with higher efficacy, such as a gate-all-around (GAA) transistor. In the GAA transistor, a gate surrounds a region in which a channel is located. In comparison to the planar transistor, the gate of the GAA transistor has a stronger channel control capability, and can better suppress a short-channel effect.

However, performance of the current semiconductor structure is still to be improved.

### SUMMARY

The present disclosure provides semiconductor structures and methods for forming the same, so as to improve performance of an NMOS transistor and a PMOS transistor and achieve high process compatibility and low process costs.

To address the above-described problem, one form of the present disclosure provides a semiconductor structure, including: a substrate, including a P-type region configured for a PMOS transistor to be formed and an N-type region configured for an NMOS transistor to be formed; a plurality of protrusions, protruding from the substrate; a first channel structure layer, suspended on the protrusions in the P-type region and including one or more first channel layers suspended at intervals, where each first channel layer is configured to improve carrier mobility in a channel of the PMOS transistor; and a second channel structure layer, suspended on the protrusions in the N-type region and including one or more second channel layers suspended at intervals, where the second channel layer includes a center channel film and a sidewall channel film arranged on a sidewall of the center channel film, and the second channel layer is configured to improve carrier mobility in a channel of the NMOS transistor.

Another form of the present disclosure provides a method for forming a semiconductor structure, including: providing a base, where the base includes a P-type region configured for a PMOS transistor to be formed and an N-type region configured for an NMOS transistor to be formed, and the base includes a substrate, a plurality of protrusions protruding from the substrate, one or more decks stacked on the protrusions in sequence, and a limiting layer on a top of each deck, the deck includes a sacrificial layer and a first channel layer on the sacrificial layer, and the first channel layer is configured to improve carrier mobility in a channel of the PMOS transistor; removing a partial thickness of the first channel layer in the N-type region along a direction parallel to the substrate, to form a first trench, where the first trench is defined by the remaining first channel layer and an adjacent sacrificial layer or by the remaining first channel layer and the adjacent sacrificial layer and the limiting layer; filling the first trench with a sidewall channel film; removing the remaining first channel layer in the N-type region, so that a second trench is defined between the sidewall channel film and the adjacent sacrificial layer or between the sidewall channel film and the adjacent sacrificial layer and the limiting layer; and filling the second trench with a center channel film, where the center channel film and the sidewall channel film are in contact with each other to form a second channel layer, and the second channel layer is configured to improve carrier mobility in a channel of the NMOS transistor; and removing the limiting layer after forming the center channel film.

Compared with the prior art, the technical solutions of embodiments and implementations of the present disclosure provide at least the following advantages.

In semiconductor structures provided in embodiments and implementations of the present disclosure, the first channel layer is configured to improve the carrier mobility in the channel of the PMOS transistor is arranged in the P-type region, and the second channel layer is arranged in the N-type region. The second channel layer includes the center channel film and the sidewall channel film on a sidewall of the center channel film. The second channel layer is configured to improve the carrier mobility in the channel of the NMOS transistor. Accordingly, the performance of the NMOS transistor and the PMOS transistor is improved, and high process compatibility and low process costs are achieved.

In methods for forming a semiconductor structure provided in embodiments and implementations of the present disclosure, in the step of providing the base, the first channel layer is configured to improve the carrier mobility in the channel of the PMOS transistor. Then a partial thickness of the first channel layer in the N-type region is removed along the direction parallel to the substrate to form the first trench, and the first trench is filled with the sidewall channel film. Subsequently, the remaining first channel layer in the N-type region is removed to form the second trench. The second trench is filled with the center channel film. The center channel film and the sidewall channel film are in contact to form the second channel layer. The second channel layer is configured to improve the carrier mobility in the channel of the NMOS transistor. Therefore, in embodiments and implementations of the present disclosure, the first channel layer is configured to improve the carrier mobility in channel of the PMOS transistor is formed in the P-type region, and the second channel layer configured to improve the carrier mobility in the channel of the NMOS transistor is formed in the N-type region. Accordingly, the performance of the NMOS transistor and the PMOS transistor is improved, and high process compatibility and low process costs are achieved.

### BRIEF DESCRIPTION OF THE DRAWINGS

FIG. 1 is a schematic structural diagram of one form of a semiconductor structure according to the present disclosure.

FIG. 2 to FIG. 19 are schematic structural diagrams of steps in one form of a method for forming a semiconductor structure according to the present disclosure.

### DETAILED DESCRIPTION

It may be learned from the background art that performance of a current semiconductor structure is still to be improved.

Specifically, for an N-type GAA transistor, when a material of a channel layer is Si, it is beneficial to improve carrier mobility in a channel of the N-type GAA transistor. For a P-type GAA transistor, when the material of the channel layer is SiGe, it is beneficial to improve carrier mobility in a channel of the P-type GAA transistor.

However, a method for simultaneously forming an N-type Si channel and a P-type SiGe channel and that has low process costs is not disclosed at present.

To address the above-described technical problems, in the semiconductor structure provided in embodiments and implementations of the present disclosure, the first channel layer configured to improve the carrier mobility in the channel of the PMOS transistor is arranged in a P-type region, and the second channel layer is arranged in an N-type region. The second channel layer includes the center channel film and the sidewall channel film on a sidewall of the center channel film. The second channel layer is configured to improve the carrier mobility in the channel of the NMOS transistor. Accordingly, the performance of the NMOS transistor and the PMOS transistor is improved, and high process compatibility and low process costs are achieved.

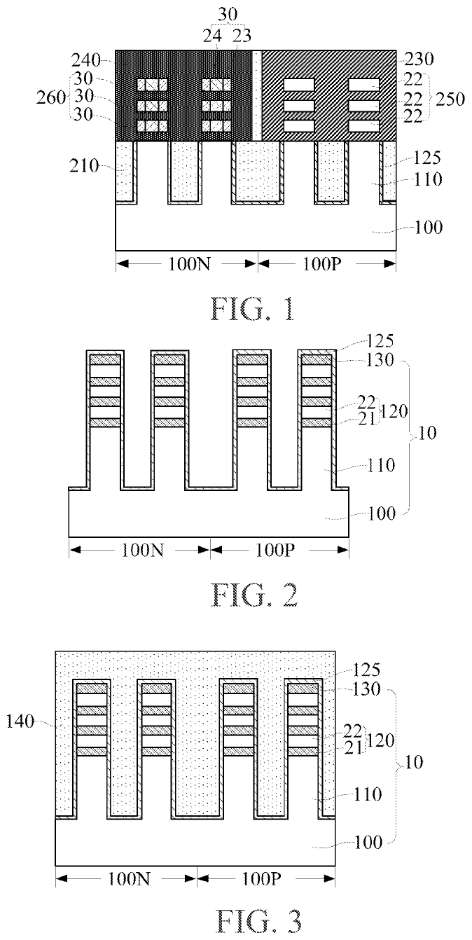

In order to make the foregoing objectives, features, and advantages of the embodiments of the present disclosure more apparent and easier to understand, specific embodiments and implementations of the present disclosure are described in detail below with reference to the accompanying drawings. FIG. 1 is a schematic structural diagram of one form of a semiconductor structure according to the present disclosure.

As shown in FIG. 1, in this form, the semiconductor structure includes: a substrate 100, where the substrate 100 includes a P-type region 100N configured to form a PMOS transistor and an N-type region 100P configured to form an NMOS transistor; a plurality of protrusions 110, protruding from the substrate 100; a first channel structure layer 250, suspended on the protrusions 110 in the P-type region 100P, where the first channel structure layer 250 includes one or more first channel layers 22 suspended at intervals, and the first channel layer 22 is configured to improve carrier mobility in a channel of the PMOS transistor; and a second channel structure layer 260, suspended on the protrusions 110 in the N-type region 100N, where the second channel structure layer 260 includes one or more second channel layers 30 suspended at intervals, the second channel layer 30 includes a center channel film 24 and a sidewall channel film 23 arranged on a sidewall of the center channel film 24, and the second channel layer 30 is configured to improve carrier mobility in a channel of the NMOS transistor.

The substrate 100 is configured to provide a process platform for the subsequent manufacture procedure. In some implementations, the substrate 100 is configured to provide the process platform for forming a gate-all-around (GAA) transistor (that is, a surrounding gate transistor).

In some implementations, the substrate 100 is a silicon substrate. That is to say, a material of the substrate 100 is monocrystalline silicon. In other implementations, the material of the substrate may further be one or more of germanium, silicon germanium, silicon carbide, gallium nitride, gallium arsenide, or indium gallium, and the substrate may further be other types of substrates such as a silicon substrate on an insulator or a germanium substrate on the insulator.

In some implementations, the protrusion 110 and the substrate 100 are integrally formed, and a material of the protrusion 110 is same as the material of the substrate 100, which are both silicon. In other implementations, the material of the protrusion may be different from the material of the substrate. The material of the protrusion may be other suitable materials, for example, one or more of germanium, silicon germanium, silicon carbide, gallium nitride, gallium arsenide, or indium gallium.

In some implementations, the semiconductor structure further includes an isolation layer 210 arranged on the substrate 100 and surrounding the protrusion 110. The first channel structure layer 250 and the second channel structure layer 260 are exposed from the isolation layer 210.

The isolation layer 210 is configured to isolate adjacent protrusions 110 and further configured to isolate the substrate 100 from a gate structure. In some implementations, a material of the isolation layer 210 is silicon oxide. The material of the isolation layer 210 may further be other insulating materials, for example one or more of silicon nitride, silicon oxynitride, or silicon germanium.

As an example, a top surface of the isolation layer 210 is flush with a top surface of the protrusion 110. In other implementations, the top surface of the isolation layer may further be lower than the top surface of the protrusion.

In some implementations, the semiconductor structure further includes a liner layer 125 arranged between the protrusion 110 and the isolation layer 210 and between the substrate 100 and the isolation layer 210.

The liner layer 125 is configured to improve adhesion between the protrusion 110 and the isolation layer 210 and between the substrate 100 and the isolation layer 210. In some implementations, a material of the liner layer 125 is silicon oxide.

The first channel structure layer 250 is configured to provide a conductive channel of the PMOS transistor. Specifically, the first channel layer 22 is configured to provide the conductive channel of the PMOS transistor.

In some implementations, a direction in which the first channel layers 22 are stacked is perpendicular to a surface of the substrate 100.

As an example, three first channel layers 22 are arranged in the first channel structure layer 250. In other implementations, another number of first channel layers may further be arranged, for example, two, four, five, and the like.

In some implementations, in order to improve performance of the PMOS transistor, a SiGe channel technology may be adopted. A material of the first channel layer 22 is silicon germanium. As an example, a mole percent of germanium in the material of the first channel layer 22 ranges from 5% to 25%.

In some other implementations, the material of the first channel layer may further be other materials that can improve the carrier mobility in the channel of the PMOS transistor. For example, the material of the first channel layer may further be one or more of germanium, gallium nitride, gallium arsenide, or indium gallium.

The second channel structure layer 260 is configured to provide a conductive channel of the NMOS transistor. Specifically, the second channel layer 30 is configured to provide the conductive channel of the NMOS transistor.

In some implementations, a direction in which the second channel layers 30 are stacked is perpendicular to a surface of the substrate 100.

As an example, three second channel layers 30 are arranged in the second channel structure layer 260. In other implementations, another number of second channel layers may further be arranged, for example, two, four, five, and the like.

In some implementations, in order to improve the performance of the NMOS transistor, a material of the second channel layer 30 is silicon. In some other implementations, the material of the second channel layer may further be other materials that can improve the carrier mobility in the channel of the NMOS transistor. For example, the material of the second channel layer may further be one or more of silicon carbide, gallium nitride, gallium arsenide, or indium gallium.

The center channel film 24 and the sidewall channel film 23 are configured to form the second channel layer 30.

The sidewall channel film 23 is configured as a support during formation of the center channel film 24.

In some implementations, a material of the center channel film 24 is the same as a material of the sidewall channel film 23, which is beneficial to improve the process compatibility. In addition, the second channel layer 30 is made of only one material, which is beneficial to improve the formation and quality of the second channel layer 30. In this way, the performance of the PMOS transistor is improved.

In some implementations, the material of the center channel film 24 and the material of the sidewall channel film 23 both include silicon. In other implementations, the center channel film and the sidewall channel film may further be other materials that can improve the carrier mobility in the channel of the NMOS transistor. In some other implementations, the material of the center channel film may further be different from the material of the sidewall channel film.

In some implementations, a thickness of the sidewall channel film 23 ranges from 1 nm to 10 nm along a direction parallel to the substrate 100.

In some implementations, the semiconductor structure further includes: a first gate structure 230, spanning the first channel structure layer 250 and filling a gap between adjacent first channel layers 22 and a gap between the protrusions 110 and the first channel layer 22 in the P-type region 100P, so that the first gate structure 230 surrounds the first channel layers 22; and a first source/drain doped region (not shown), arranged on two sides of the first gate structure 230 and in contact with ends of the first channel layers 22. The first gate structure 230 is configured to control opening and closing of the conductive channel of the PMOS transistor.

In some implementations, the first gate structure 230 is a metal gate structure. The first gate structure 230 includes a first gate dielectric layer (not shown) and a first gate electrode layer (not shown) on the first gate dielectric layer. The first gate dielectric layer is configured to isolate the first gate electrode layer from the first channel layer 22.

The first source/drain doped region is configured as a source or a drain of the PMOS transistor. During operation of the PMOS transistor, the first source/drain doped region is configured to provide a carrier source.

In some implementations, the first source/drain doped region includes a stress layer doped with ions. The stress layer is configured to provide a stress for a channel region, thereby improving carrier mobility. In some implementations, the first source/drain doped region includes a stress layer doped with P-type ions. A material of the stress layer is Si or SiGe.

The second gate structure 240 is configured to control opening and closing of the conductive channel of the NMOS transistor.

In some implementations, the second gate structure 240 is a metal gate structure, and the second gate structure includes a second gate dielectric layer (not shown) and a second gate electrode layer (not shown) on the second gate dielectric layer. The second gate dielectric layer is configured to isolate the second gate electrode layer from the second channel layer 30.

In some implementations, the semiconductor structure further includes: a second gate structure 240, spanning the second channel structure layer 260 and filling a gap between adjacent second channel layers 30 and a gap between the protrusions 110 and the second channel layer 30 in the N-type region 100N, so that the second gate structure 240 surrounds the second channel layer 30; and a second source/drain doped region (not shown), arranged on two sides of the second gate structure 240 and in contact with ends of the second channel layers 30.

The second source/drain doped region is configured as a source or a drain of the NMOS transistor. During operation of the NMOS transistor, the second source/drain doped region is configured to provide a carrier source. In some implementations, the second source/drain doped region includes a stress layer doped with N-type ions. A material of the stress layer is Si or SiC.

The present disclosure further provides a method for forming a semiconductor structure. FIG. 2 to FIG. 19 are schematic structural diagrams of steps in one form of a method for forming a semiconductor structure according to the present disclosure. A method for forming a semiconductor structure in this form is described in detail below with reference to the accompanying drawings.

Referring to FIG. 2, a base 10 is provided, including a P-type region 100P configured for a PMOS transistor to be formed and an N-type region 100N configured for an NMOS transistor to be formed. The base 10 includes a substrate 100, a plurality of protrusions 110 protruding from the substrate 100, one or more decks 120 stacked on the protrusions 110 in sequence, and a limiting layer 130 on a top of each deck 120. Each deck 120 includes a sacrificial layer 21 and a first channel layer 22 on the sacrificial layer 21. The first channel layer 22 is configured to improve carrier mobility in a channel of the PMOS transistor.

The base 10 is configured to provide a process platform for the subsequent manufacture procedure. In some implementations, the base 10 is configured to provide the process platform for forming a GAA transistor (that is, a surrounding gate transistor).

In some implementations, the substrate 100 is a silicon substrate. In other implementations, the material of the substrate may further be one or more of germanium, silicon germanium, silicon carbide, gallium nitride, gallium arsenide, or indium gallium, and the substrate may further be other types of substrates such as a silicon substrate on an insulator or a germanium substrate on the insulator.

In some implementations, the protrusion 110 and the substrate 100 are integrally formed, and a material of the protrusion 110 is same as the material of the substrate 100, which are both silicon. In other implementations, the material of the protrusion may be different from the material of the substrate. The material of the protrusion may be other suitable materials, for example, one or more of germanium, silicon germanium, silicon carbide, gallium nitride, gallium arsenide, or indium gallium.

The deck 120 is configured to provide a process basis for subsequent formation of first channel layers 22 suspended at intervals in the P-type region 100P and second channel layers suspended at intervals in the N-type region 100N.

Specifically, the first channel layer 22 is configured to provide a conductive channel of a field effect transistor, and the sacrificial layer 21 is configured to support the first channel layer 22, thereby providing the process basis for subsequently implementing the spaced suspension arrangement of the first channel layers 22. The sacrificial layer 21 is further configured to provide a spatial position for subsequently forming a gate structure.

In some implementations, a material of the first channel layer 22 includes silicon germanium, a material of the sacrificial layer 21 includes silicon germanium, and a mole percent of germanium in the material of the sacrificial layer 21 is greater than a mole percent of germanium in the material of the first channel layer 22.

The material of the first channel layer 22 includes silicon germanium, which is beneficial to improve the carrier mobility in the channel of the PMOS transistor. In some other implementations, the material of the first channel layer may further be other materials that can improve the carrier mobility in the channel of the PMOS transistor. For example, the material of the first channel layer may further be one or more of germanium, gallium nitride, gallium arsenide, or indium gallium.

The mole percent of germanium in the material of the sacrificial layer 21 is greater than the mole percent of germanium in the material of the first channel layer 22, so that there is an etch selectivity of the material of the sacrificial layer 21 to the material of the first channel layer 22. Furthermore, in a subsequent step of removing the sacrificial layer 21, a probability that the first channel layer 22 is damaged can be reduced, quality of the channel layer of the PMOS transistor is enhanced, and performance of the PMOS transistor is correspondingly improved.

The mole percent of the germanium in the material of the first channel layer 22 should be neither excessively low nor excessively high. If the mole percent of germanium in the material of the first channel layer 22 is excessively low, the effect of improving the carrier mobility in the channel of the PMOS transistor may not be obvious. If the mole percent of the germanium in the first channel layer 22 is excessively high, a difference between the mole percent of the germanium in the first channel layer 22 and the mole percent of the germanium in the sacrificial layer 21 may be excessively small, which may lead to an excessively low etch selectivity of the first channel layer 22 to the sacrificial layer 21. Accordingly, the probability that the first channel layer 22 is damaged during the subsequent removal of the sacrificial layer 21 is easily increased. Therefore, in some implementations, the mole percent of germanium in the material of the first channel layer 22 ranges from 5% to 25%.

The mole percent of the germanium in the material of the sacrificial layer 21 should be neither excessively low nor excessively high. If the mole percent of the germanium in the material of the sacrificial layer 21 is excessively low, the difference between the mole percent of germanium in the material of the sacrificial layer 21 and the mole percent of germanium in the material of the first channel layer 22 is likely to be excessively small, and therefore the etch selectivity of the sacrificial layer 21 to the first channel layer 22 is not easily increased. If the mole percent of germanium in the material of the sacrificial layer 21 is excessively high, the difficulty of forming the sacrificial layer 21 is easily increased. Therefore, In some implementations, the mole percent of germanium in the material of the sacrificial layer 21 ranges from 30% to 50%.

In some implementations, a plurality of decks 120 are arranged, and a direction in which the plurality of decks 120 are stacked is perpendicular to a surface of the substrate 100. As an example, three decks 120 are arranged. In other implementations, another number of decks may further be arranged, for example, two, four, five, and the like.

The limiting layer 130 is configured to subsequently define a position at which the second channel layer is formed.

In some implementations, a material of the limiting layer 130 is the same as the material of the sacrificial layer 21, which is beneficial to improve the process compatibility. In other implementations, the material of the limiting layer may further be different from the material of the sacrificial layer.

Still referring to FIG. 2, the forming method further includes forming a first liner layer 125 on a top of the substrate 100, a sidewall of the protrusion 110, a sidewall of the deck 120, and a top surface and a sidewall of the limiting layer 130.

The first liner layer 125 is configured to protect the deck 120 in the subsequent process, and further configured to improve adhesion between the protrusion 110 and the substrate 100 and a subsequent isolation layer.

In some implementations, a material of the first liner layer 125 includes silicon oxide.

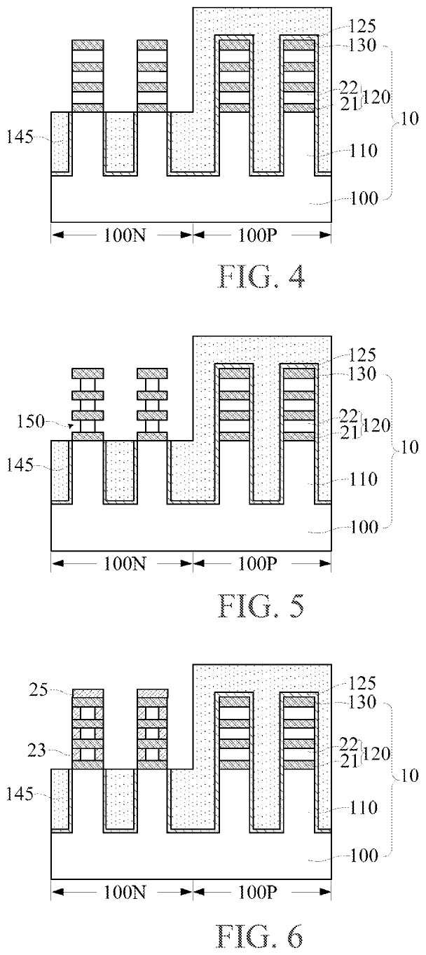

Referring to FIG. 3 to FIG. 4, after providing the base 10, the forming method further includes forming a first cover film 145 on the substrate 100 around the protrusion 110. The first cover film 145 covers a sidewall of the deck 120 and the sidewall and a top of the limiting layer 130 in the P-type region 100P, and the deck 120 and the limiting layer 130 in the N-type region 100N are exposed from the first cover film.

The first cover film 145 is configured to subsequently remove a partial thickness of the first channel layer 22 in the N-type region 100N along a direction parallel to the substrate 100 and protect the P-type region 100P during formation of a sidewall channel film.

In some implementations, a material of the first cover film 145 is a dielectric material, so that the material of the first cover film 145 can be subsequently reserved to be configured as a material of the isolation layer. As an example, the material of the first cover film 145 includes one or more of silicon oxide, silicon nitride, or silicon oxynitride.

Specifically, in some implementations, the step of forming the first cover film 145 includes:

forming, on the substrate 100, an initial cover film 140 surrounding the protrusion 110, the deck 120, and the limiting layer 130, as shown in FIG. 3, where the initial cover film 140 further covers the top of the limiting layer 130. Specifically, the initial cover film 140 covers the first liner layer 125.

A partial thickness of the initial cover film 140 in the N-type region 100N is subsequently removed, and the remaining initial cover film 140 is configured as the first cover film 145.

As an example, the initial cover film 140 is formed using a flowable chemical vapor deposition process. The flowable chemical vapor deposition process has a high gap filling capability, which is beneficial to improve filling and quality of the initial cover film 140 between the decks 120 and between the protrusions 110.

As shown in FIG. 4, the partial thickness of the initial cover film 140 in the N-type region 100N is removed, the remaining initial cover film 140 is configured as the first cover film 145, and the deck 120 and the limiting layer 130 in the N-type region 100N are exposed from the first cover film 145.

Specifically, in some implementations, the first liner layer 125 in the N-type region 100N is used as a stop position, and the partial thickness of the initial cover film 140 in the N-type region 100N is removed, which is beneficial to reduce a probability of etching of the deck 120 in the N-type region 100N by mistake caused by the process of removing the partial thickness of the initial cover film 140 in the N-type region 100N.

Accordingly, the first liner layer 125 in the N-type region 100N is exposed from the first cover film 145.

Therefore, in some implementations, after the partial thickness of the initial cover film 140 in the N-type region 100N is removed, and before the partial thickness of the first channel layer 22 in the N-type region 100N is removed along the direction parallel to the substrate 100, the method for forming a semiconductor structure further includes removing the sidewall of the deck 120 in the N-type region 100N and the first liner layer 125 on the top surface and the sidewall of the limiting layer 130, so as to expose the deck 120 in the N-type region 100N.

Specifically, the sidewall of the deck 120 and the first liner layer 125 on the top surface and the sidewall of the limiting layer 130 in the N-type region 100N are removed using an isotropic etching process (for example, a wet etching process). A thickness of the first liner layer 125 is small, and therefore the etching process of removing the sidewall of the deck 120 and the first liner layer 125 on the top surface and the sidewall of the limiting layer 130 in the N-type region 100N is simple and has high process compatibility.

Referring to FIG. 5, the partial thickness of the first channel layer 22 in the N-type region 100N is removed along the direction parallel to the substrate 100, to form a first trench 150. The first trench 150 is defined by the remaining first channel layer 22 and an adjacent sacrificial layer 21 or by the remaining first channel layer 22 and the adjacent sacrificial layer 21 and the limiting layer 130. The first trench 150 is configured to provide a spatial position for subsequent formation of the sidewall channel film.

It should be noted that, the thickness of the first channel layer 22 in the N-type region 100N that is removed along the direction parallel to the substrate 100 should be neither excessively small nor excessively large. If the removed thickness is excessively small, a size of the first trench 150 along the direction parallel to the substrate 100 is excessively small, and a thickness of the sidewall channel film subsequently formed in the first trench 150 is also excessively small. Therefore, a probability that the sidewall channel film is completely consumed in the subsequent process of removing the remaining first channel layer 22 in the N-type region 100N may be easily increased. If the removed thickness is excessively large, a size of the remaining first channel layer 22 in the N-type region 100N is excessively small, which may easily cause an excessively low mechanical strength of the remaining first channel layer 22 in the N-type region 100N, may easily increase the probability of collapse of the sacrificial layer 21 in the N-type region 100N, and may easily increase the process difficulty of subsequent removal of the remaining first channel layer 22 in the N-type region 100N. Furthermore, a size of a second trench formed by subsequent removal of the remaining first channel layer 22 in the N-type region 100N is excessively small, which may easily increase the process difficulty of subsequent formation of the center channel film in the second trench. Therefore, in some implementations, the thickness of the first channel layer 22 in the N-type region 100N that is removed along the direction parallel to the substrate 100 ranges from 1 nm to 10 nm.

In some implementations, the partial thickness of the first channel layer 22 in the N-type region 100N is removed along the direction parallel to the substrate 100 using the isotropic etching process. The isotropic etching process has the characteristic of isotropic etching, so that the first channel layer 22 in the N-type region 100N can be etched along the direction parallel to the substrate 100.

Referring to FIG. 6, the first trench 150 is filled with a sidewall channel film 23.

The sidewall channel film 23 is configured to subsequently form the second channel layer with the center channel film, and is further configured to define a position at which the center channel film is formed during subsequent formation of the center channel film. In addition, the sidewall channel film 23 is further configured to support the sacrificial layer 21 in the N-type region 100N during subsequent removal of the remaining first channel layer 22 in the N-type region 100N and subsequent formation of the center channel film. In this way, the sacrificial layer 21 is prevented from collapsing or leaning, and formation of the second channel layer is accordingly guaranteed.

Accordingly, a material that can improve the carrier mobility in the channel of the NMOS transistor is selected as a material of the sidewall channel film 23. As an example, the material of the sidewall channel film 23 is silicon, which not only improves the carrier mobility in the channel of the NMOS transistor, but also reduces process costs and improves the process compatibility.

In some other implementations, the material of the sidewall channel film may further be other materials that can improve the carrier mobility in the channel of the NMOS transistor. For example, the material of the sidewall channel film may further be one or more of silicon carbide, gallium nitride, gallium arsenide, or indium gallium.

In some implementations, the process of filling the first trench 150 with the sidewall channel film 23 includes an epitaxy process. Specifically, In some implementations, the step of forming the sidewall channel film 23 includes: epitaxially growing a first channel epitaxial layer (not shown) in the first trench 150 by using the epitaxy process, where the first channel epitaxial layer is further formed on the sidewall of the sacrificial layer 21 in the N-type region 100N and the top and the sidewall of the limiting layer 130; and removing the first channel epitaxial layer on the sidewall of the sacrificial layer 21 and the sidewall of the limiting layer 130 in the N-type region 100N, where the remaining first channel epitaxial layer in the first trench 150 is configured as the sidewall channel film 23.

In some implementations, the first channel epitaxial layer on the sidewall of the sacrificial layer 21 and the sidewall of the limiting layer 130 in the N-type region 100N is removed by combining the isotropic etching process and the anisotropic etching process. The isotropic etching process is used for reducing a size of the first channel epitaxial layer along the direction parallel to the substrate 100, and the anisotropic etching process is used for causing a sidewall of the remaining first channel epitaxial layer to be flush with the sidewall of the sacrificial layer 21.

It should be noted that, in some implementations, in the process of forming the sidewall channel film 23 by the epitaxy process, a sacrificial channel film 25 is further formed on a top of the limiting layer 130 in the N-type region 100N. Specifically, in the step of removing the first channel epitaxial layer on the sidewall of the sacrificial layer 21 in the N-type region 100N, a partial thickness of the first channel epitaxial layer on the top of the limiting layer 130 in the N-type region 100N is reserved as the sacrificial channel film 25.

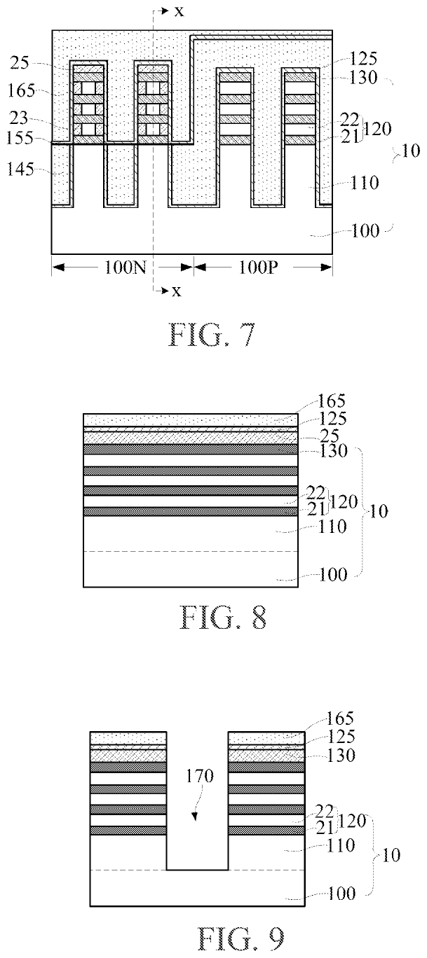

Referring to FIG. 7 to FIG. 9, FIG. 8 is a cross-sectional view of FIG. 7 along a direction xx, and FIG. 9 is a cross-sectional view based on FIG. 8. After forming the sidewall channel film 23, the forming method further includes forming, on the N-type region 100N, a cutting groove 170 that cuts the limiting layer 130, the sacrificial layer 21, the first channel layer 22, and the protrusion 110 along an extending direction of the protrusion 110, so as to expose the first channel layer 22 in the N-type region 100N.

The cutting groove 170 is formed to disconnect the limiting layer 130, the sacrificial layer 21, the first channel layer 22, and the protrusion 110 at a desired position, to form an active region pattern of the N-type region 100N. Furthermore, the first channel layer 22 in the N-type region 100N is exposed from the cutting groove 170, so that the remaining first channel layer 22 in the N-type region 100N is subsequently removed.

It should be noted that, in some implementations, after forming the sidewall channel film 23 and before forming the cutting groove 170, the method for forming a semiconductor structure further includes forming a filling layer 165 in the N-type region 100N. The filling layer 165 covers the sidewall channel film 23 and the sidewall of the sacrificial layer 21 and the sidewall and the top of the limiting layer 130. Specifically, the filling layer 165 is formed on the first cover film 145 in the N-type region.

The filling layer 165 is configured to provide a flat surface for the subsequent process.

In some implementations, a material of the filling layer 165 is the dielectric material. Therefore, after the remaining first channel layer 22 in the N-type region 100N is subsequently removed and the center channel film is formed, the remaining filling layer 165 is not required to be removed, which is beneficial to simplify process steps accordingly. As an example, the material of the filling layer 165 includes one or more of silicon oxide, silicon nitride, or silicon oxynitride.

In some implementations, the filling layer 165 is formed by using a flowable chemical vapor deposition process.

In other implementations, the material of the filling layer may further be spin-on carbon (SOC). Correspondingly, the filling layer is formed by using a spin coating process. The spin coating process is simple, has low process costs, and can improve flatness of a top surface of the filling layer.

Correspondingly, in the step of forming the cutting groove 170, the cutting groove 170 further extends through the filling layer 165 in the N-type region 100N along a direction perpendicular to the extending direction of the protrusion 110.

It should be noted that, in some implementations, after forming the sidewall channel film 23 and before forming the filling layer 165, the method for forming a semiconductor structure further includes forming a second liner layer 155 on the sidewall channel film 23 and the sidewalls of the sacrificial layer 21 and the limiting layer in the N-type region.

The second liner layer 155 is configured to protect the sidewall channel film 23 in the N-type region 100N. As an example, a material of the second liner layer 155 includes one or more of silicon, silicon oxide, silicon nitride, or silicon oxynitride.

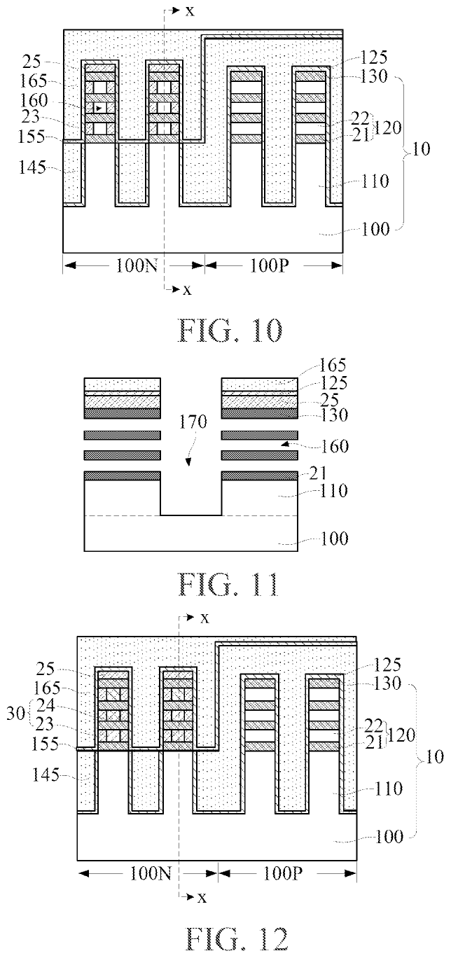

Referring to FIG. 10 and FIG. 11, FIG. 11 is a cross-sectional view of FIG. 10 along a direction xx. The remaining first channel layer 22 in the N-type region 100N is removed, so that a second trench 160 is defined between the sidewall channel film 23 and the adjacent sacrificial layer 21, or between the sidewall channel film 23 and the adjacent sacrificial layer 21 and the limiting layer 130.

The second trench 160 is configured to provide a spatial position for formation of the center channel film, and is further configured to define a formation region of the center channel film. In the step of forming the second trench 160, the sidewall channel film 23 is configured as a support, thereby preventing the sacrificial layer 21 from collapsing or leaning.

Specifically, in some implementations, the remaining first channel layer 22 in the N-type region 100N is removed through the sidewall of the first channel layer 22 exposed from the cutting groove 170. The process of forming the cutting groove 170 may be integrated with the process of removing the remaining first channel layer 22 in the N-type region 100N, which is beneficial to improve the process integration level and process compatibility, simplify process steps, and reduce process costs.

In some implementations, the remaining first channel layer 22 in the N-type region 100N is removed using an isotropic etching process. The isotropic etching process has the characteristic of isotropic etching, so that the remaining first channel layer 22 in the N-type region 100N is easily removed.

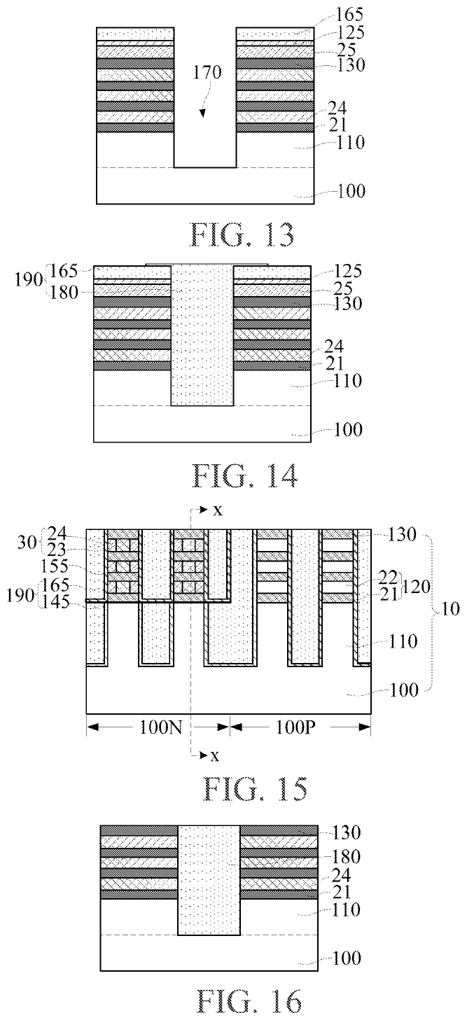

Referring to FIG. 12 and FIG. 13, FIG. 13 is a cross-sectional view of FIG. 12 along a direction xx. The second trench 160 is filled with the center channel film 24. The center channel film 24 and the sidewall channel film 23 are in contact to form a second channel layer 30, and the second channel layer 30 is configured to improve the carrier mobility in the channel of the NMOS transistor.

The center channel film 24 and the sidewall channel film 23 are in contact to form the second channel layer 30. The second channel layer 30 is configured to improve the carrier mobility in the channel of the NMOS transistor. Therefore, in some implementations, the first channel layer 22 configured to improve the carrier mobility in the channel of the PMOS transistor is formed in the P-type region 100P, and the second channel layer 30 configured to improve the carrier mobility in the channel of the NMOS transistor is formed in the N-type region 100N. Accordingly, the performance of the NMOS transistor and the PMOS transistor is improved, and high process compatibility and low process costs are achieved.

In some implementations, a material of the center channel film 24 is the same as a material of the sidewall channel film 23, which is beneficial to improve the process compatibility. In addition, the second channel layer 30 is made of one material, which is beneficial to improve the formation and quality of the second channel layer 30. In this way, the performance of the PMOS transistor is improved.

In some implementations, the material of the center channel film 24 includes silicon. In other implementations, the center channel film may further be other materials that can improve the carrier mobility in the channel of the NMOS transistor. In some other implementations, the material of the center channel film may further be other materials that can improve the carrier mobility in the channel of the NMOS transistor. For example, the material of the center channel film may further be one or more of silicon carbide, gallium nitride, gallium arsenide, or indium gallium.

In some other implementations, the material of the center channel film may further be different from the material of the sidewall channel film.

In some implementations, an etch selectivity of the material of the second channel layer 30 to the material of the sacrificial layer 21 is relatively high. Therefore, in the subsequent step of removing the sacrificial layer 21, the probability that the second channel layer 30 is damaged can be reduced, thereby ensuring the quality of the second channel layer 30 and correspondingly improving the performance of the NMOS transistor.

In some implementations, the process of filling the second trench 160 with the center channel film 24 includes an epitaxy process. Specifically, the step of forming the center channel film 24 includes: forming a second channel epitaxial layer (not shown) in the second trench 160 by using the epitaxy process, where the second channel epitaxial layer is further formed on the sidewalls of the sacrificial layer 21, the limiting layer 130, and the sacrificial channel film 25 exposed from the cutting groove 170; and removing the second channel epitaxial layer on the sidewalls of the sacrificial layer 21, the limiting layer 130, and the sacrificial channel film 25, where the remaining second channel epitaxial layer in the second trench 160 is configured as the center channel film 24.

In some implementations, the second channel epitaxial layer on the sidewall of the sacrificial layer 21 is removed by combining the isotropic etching process and the anisotropic etching process. The isotropic etching is to transversely etch the second channel epitaxial layer along the direction parallel to the substrate 100, and the anisotropic etching process is to cause the sidewall of the remaining second channel epitaxial layer to be flush with the sidewall of the sacrificial layer 21.

In some implementations, after the second channel layer 30 is formed, the sacrificial layer 21 in the P-type region 100P and adjacent first channel layers 22 on the sacrificial layer 21 are configured to form a first channel deck (not shown), and the sacrificial layer 21 in the N-type region 100N and adjacent second channel layers 30 on the sacrificial layer 21 are configured to form a second channel deck (not shown).

In some implementations, the first channel deck and the second channel deck have the same sacrificial layer 21, so as to avoid introducing the sacrificial layer 21 made of an additional material, thereby improving the process compatibility.

It should be noted that, in some implementations, the first channel layer 22 configured to improve the carrier mobility in the channel of the PMOS transistor is formed in the P-type region 100P, the second channel layer 30 configured to improve the carrier mobility in the channel of the NMOS transistor is formed in the N-type region 100N, and an additional photomask is not required. Therefore, the process compatibility is improved and process costs are reduced while improving the performance of the NMOS transistor and the PMOS transistor.

Referring to FIG. 14, a cross-sectional view based on FIG. 13 is shown. After forming the center channel film 24, the method for forming a semiconductor structure further includes forming a second cover film 180 filling the cutting groove 170. The second cover film 180, the filling layer 165, and the first cover film 145 are configured to form a cover layer 190.

The cover layer 190 is configured to protect the first channel layer 22 and the second channel layer 30 in the subsequent step of removing the limiting layer 130.

In some implementations, a material of the second cover film 180 is a dielectric material, so that the material of the cover layer 190 is the dielectric material. Accordingly, the cover layer 190 is configured to subsequently form an isolation layer without needing to remove the cover layer 190.

In some implementations, the process of forming the second cover film 180 includes a flowable chemical vapor deposition process.

In some implementations, the filling layer 165 is used as the dielectric material by way of example for description, and the filling layer 165 is reserved by way of example for description. In other implementations, after forming the second channel layer and before removing the limiting layer, the method for forming a semiconductor structure further includes: removing the filling layer; and forming a second cover film on the first cover film in the N-type region after the filling layer is removed. The second cover film covers sidewalls of the second channel layer and the sacrificial layer, and is arranged above a top of the limiting layer, and the second cover film and the first cover film are configured to form the cover layer.

Referring to FIG. 15 and FIG. 16, FIG. 16 is a cross-sectional view of FIG. 15 along a direction xx. The cover layer 190 higher than the top surface of the limiting layer 130 is removed to expose the limiting layer 130. The limiting layer 130 is exposed for subsequent removal of the limiting layer 130.

In some implementations, the cover layer 190 higher than the top surface of the limiting layer 130 is removed by using a planarization process. As an example, the cover layer 190 higher than the top surface of the limiting layer 130 is removed by using a chemical mechanical planarization process.

In the step of removing the cover layer 190 higher than the top surface of the limiting layer 130, the sacrificial channel film 25 and a second liner layer 155 higher than the top surface of the limiting layer 130 are further removed.

Referring to FIG. 17, after the center channel film 24 is formed, the limiting layer 130 is removed.

The limiting layer 130 is removed so that a first dummy gate structure can span the first channel deck, and a second dummy gate structure can span the second channel deck.

In some implementations, the step of removing the limiting layer 130 includes removing the limiting layer 130 exposed from the cover layer 190. Specifically, in some implementations, the limiting layer 130 is removed using one or two of a dry etching process and a wet etching process.

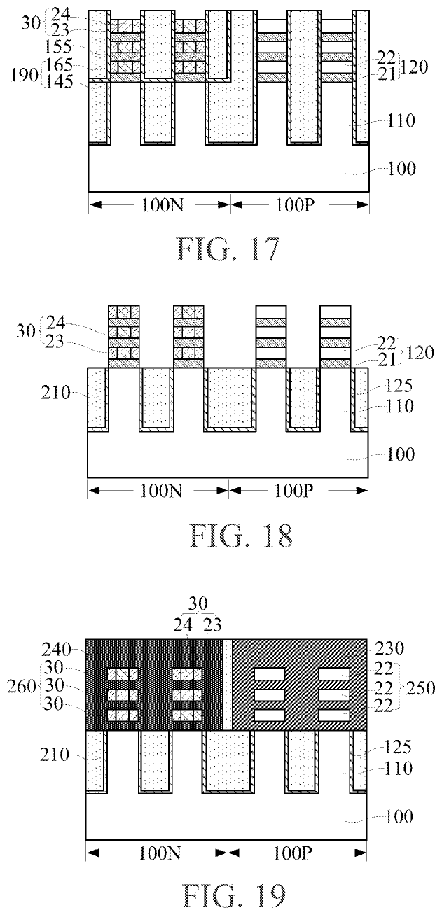

In some implementations, a material of the cover layer 190 is a dielectric material. Referring to FIG. 18, the method for forming a semiconductor structure further includes removing a partial thickness of the cover layer 190 after the limiting layer is removed. The remaining cover layer 190 is configured as an isolation layer 210, and the sacrificial layer 21, the first channel layer 22, and the second channel layer 30 are exposed from the isolation layer 210.

The isolation layer 210 is configured to isolate adjacent protrusions 110 and further configured to isolate the substrate 100 from a subsequent gate structure.

In some implementations, the partial thickness of the cover layer 190 is removed, and the remaining cover layer 190 is configured as the isolation layer 210. Therefore, the process integration level and the process compatibility can be improved by combining the process of forming the second channel layer 30 with the process of forming the isolation layer 210.

Referring to FIG. 19, the method for forming a semiconductor structure further includes: forming a first dummy gate structure (not shown) spanning the first channel deck and a second dummy gate structure (not shown) spanning the second channel deck after removing the limiting layer 130; forming a first source/drain doped region (not shown) in the first channel deck on two sides of the first dummy gate structure; forming a second source/drain doped region (not shown) in the second channel deck on two sides of the second dummy gate structure; removing the first dummy gate structure to form a first gate opening (not shown), to expose the first channel deck; removing the sacrificial layer exposed from the first gate opening to form a first groove (not shown), where the first groove is in communication with the first gate opening; filling the first gate opening and the first groove with the first gate structure 230, so that the first gate structure 230 surrounds the first channel layer 22; removing the second dummy gate structure to form a second gate opening (not shown), to expose the second channel deck; removing the sacrificial layer exposed from the second gate opening to form a second groove (not shown), where the second groove is in communication with the second gate opening; and filling the second gate opening and the second groove with the second gate structure 240, so that the second gate structure 240 surrounds the second channel layer 30.

The first dummy gate structure is configured to provide a spatial position for forming the first gate structure.

As an example, the first dummy gate structure includes a first dummy gate oxide layer and a first dummy gate layer on the first dummy gate oxide layer. A material of the first dummy gate oxide layer is one or more of silicon oxide or silicon oxynitride. A material of the first dummy gate layer includes one or more of polycrystalline silicon or amorphous silicon.

The first source/drain doped region is configured as a source or a drain of the PMOS transistor. During operation of the PMOS transistor, the first source/drain doped region is configured to provide a carrier source.

In some implementations, the first source/drain doped region includes a stress layer doped with ions. The stress layer is configured to provide a stress for a channel region, thereby improving carrier mobility. In some implementations, the first source/drain doped region includes a stress layer doped with P-type ions. A material of the stress layer is Si or SiGe.

In some implementations, after the sacrificial layer 21 exposed from the first gate opening is removed, one or more first channel layers 22 suspended at intervals and the protrusion 110 are suspended at intervals to form a first channel structure layer 250.

The second dummy gate structure is configured to provide a spatial position for forming the second gate structure.

As an example, the second dummy gate structure includes a second dummy gate oxide layer and a second dummy gate layer on the second dummy gate oxide layer. A material of the second dummy gate oxide layer includes one or more of silicon oxide or silicon oxynitride. A material of the second dummy gate layer includes one or more of polycrystalline silicon or amorphous silicon.

The second source/drain doped region is configured as a source or a drain of the NMOS transistor. During operation of the NMOS transistor, the second source/drain doped region is configured to provide a carrier source. In some implementations, the second source/drain doped region includes a stress layer doped with N-type ions. A material of the stress layer is Si or SiC.

In some implementations, after the sacrificial layer 21 exposed from the second gate opening is removed, one or more second channel layers 30 suspended at intervals and the protrusion 110 are suspended at intervals to form a second channel structure layer 260.

The first gate structure 230 is configured to control opening and closing of the conductive channel of the PMOS transistor. In some implementations, the first gate structure 230 spans the first channel structure layer 250.

In some implementations, the first gate structure 230 is a metal gate structure. The first gate structure 230 includes a first gate dielectric layer (not shown) and a first gate electrode layer (not shown) on the first gate dielectric layer. The first gate dielectric layer is configured to isolate the first gate electrode layer from the first channel layer 22.

The second gate structure 240 is configured to control opening and closing of the conductive channel of the NMOS transistor. In some implementations, the second gate structure 240 spans the second channel structure layer 260.

In some implementations, the second gate structure 240 is a metal gate structure, and the second gate structure includes a second gate dielectric layer (not shown) and a second gate electrode layer (not shown) on the second gate dielectric layer. The second gate dielectric layer is configured to isolate the second gate electrode layer from the second channel layer 30.

Although the present disclosure is described above, the present disclosure is not limited thereto. Any person skilled in the art can make various changes and modifications without departing from the spirit and the scope of the present disclosure. Therefore, the protection scope of the present disclosure should be subject to the scope defined by the claims.

What is claimed is:

1. A semiconductor structure, comprising:
a substrate, comprising a P-type region configured for a PMOS transistor to be formed and an N-type region configured for an NMOS transistor to be formed;
a plurality of protrusions, protruding from the substrate;
a first channel structure layer, suspended on the protrusions in the P-type region and comprising one or more first channel layers suspended at intervals, wherein each of the first channel layers is configured to improve carrier mobility in a channel of the PMOS transistor; and
a second channel structure layer, suspended on the protrusions in the N-type region and comprising one or more second channel layers suspended at intervals, wherein each of the second channel layers comprises a center channel film and a sidewall channel film arranged on a sidewall of the center channel film, and each of the second channel layers is configured to improve carrier mobility in a channel of the NMOS transistor.

2. The semiconductor structure according to claim 1, further comprising:
a first gate structure, spanning the first channel structure layer and filling a gap between adjacent first channel layers and a gap between the protrusions in the P-type region and the first channel layer, so that the first gate structure surrounds the first channel layer;
a first source/drain doped region, arranged on two sides of the first gate structure and in contact with ends of the first channel layers;
a second gate structure, spanning the second channel structure layer and filling a gap between second channel layers and a gap between the protrusions in the N-type region and the second channel layer, so that the second gate structure surrounds the second channel layer; and
a second source/drain doped region, arranged on two sides of the second gate structure and in contact with ends of the second channel layers.

3. The semiconductor structure according to claim 1, wherein a thickness of the sidewall channel film ranges from 1 nm to 10 nm in a direction parallel to the substrate.

4. The semiconductor structure according to claim 1, wherein a material of the center channel film is the same as a material of the sidewall channel film.

5. The semiconductor structure according to claim 1, wherein the materials of the center channel film and the sidewall channel film comprise at least one of silicon, silicon carbide, gallium nitride, gallium arsenide, or indium gallium.

6. The semiconductor structure according to claim 1, wherein a material of the first channel layer comprises at least one of silicon germanium, germanium, gallium nitride, gallium arsenide, or indium gallium.

7. The semiconductor structure according to claim 6, wherein a mole percent of germanium in the first channel layer ranges from 5% to 25%.

8. A method for forming a semiconductor structure, comprising:
providing a base, wherein the base comprises a P-type region configured for a PMOS transistor to be formed and an N-type region configured for an NMOS transistor to be formed, and the base comprises a substrate, a plurality of protrusions protruding from the substrate, one or more decks stacked on the protrusions in sequence, and a limiting layer on a top of each of the decks, wherein each of the decks comprises a sacrificial layer and a first channel layer on the sacrificial layer, and wherein the first channel layer is configured to improve carrier mobility in a channel of the PMOS transistor;
removing a partial thickness of the first channel layer in the N-type region along a direction parallel to the substrate, to form a first trench, wherein the first trench is defined by the remaining first channel layer and an adjacent sacrificial layer or by the remaining first channel layer and the adjacent sacrificial layer and the limiting layer;
filling the first trench with a sidewall channel film;
removing the remaining first channel layer in the N-type region, so that a second trench is defined between the sidewall channel film and the adjacent sacrificial layer or between the sidewall channel film and the adjacent sacrificial layer and the limiting layer;
filling the second trench with a center channel film, wherein the center channel film and the sidewall channel film are in contact with each other to form a second channel layer, and the second channel layer is configured to improve carrier mobility in a channel of the NMOS transistor; and
removing the limiting layer after forming the center channel film.

9. The method for forming a semiconductor structure according to claim 8, further comprising:
forming, on the N-type region, a cutting groove that cuts the limiting layer, the sacrificial layer, the first channel layer, and each of the protrusions along an extending direction of the protrusion after forming the sidewall channel film and before removing the remaining first channel layer in the N-type region, so as to expose the first channel layer in the N-type region;
wherein the step of removing the remaining first channel layer in the N-type region comprises: removing the remaining first channel layer in the N-type region through a sidewall of the first channel layer exposed from the cutting groove.

10. The method for forming a semiconductor structure according to claim 9, wherein after forming the sidewall channel film and before forming the cutting groove, the method for forming a semiconductor structure further comprises:
forming a filling layer in the N-type region, wherein the filling layer covers the sidewall channel film and a sidewall of the sacrificial layer and a sidewall and a top of the limiting layer; and
in the step of forming the cutting groove, the cutting groove further extends through the filling layer in the N-type region along a direction perpendicular to the extending direction of the protrusion.

11. The method for forming a semiconductor structure according to claim 10, wherein:
after providing the base and before removing the partial thickness of the first channel layer in the N-type region along the direction parallel to the substrate, the method for forming a semiconductor structure further comprises: forming, on the substrate, a first cover film around the protrusion, wherein the first cover film covers a sidewall of the deck in the P-type region and the sidewall and the top of the limiting layer, and the deck and the limiting layer in the N-type region are exposed from the first cover film, wherein in the step of forming the filling layer, the filling layer is formed on the first cover film in the N-type region; and
after forming the second channel layer and before removing the limiting layer, the method for forming a semiconductor structure further comprises:
forming a second cover film filling the cutting groove, wherein the second cover film, the filling layer, and the first cover film are configured to form a cover layer; removing the cover layer higher than a top surface of the limiting layer to expose the limiting layer; or
removing the filling layer; forming a second cover film on the first cover film in the N-type region after removing the filling layer, wherein the second cover film covers sidewalls of the second channel layer and the sacrificial layer and is arranged above the top of the limiting layer, and the second cover film and the first cover film are configured to form a cover layer; and removing the cover layer higher than a top surface of the limiting layer to expose the limiting layer,
wherein the step of removing the limiting layer comprises: removing the limiting layer exposed from the cover layer.

12. The method for forming a semiconductor structure according to claim 11, wherein:
a material of the cover layer is a dielectric material; and
the method for forming a semiconductor structure further comprises: removing a partial thickness of the cover layer after removing the limiting layer, wherein the remaining cover layer is configured as an isolation layer, and the sacrificial layer, the first channel layer, and the second channel layer are exposed from the isolation layer.

13. The method for forming a semiconductor structure according to claim 11, wherein the cover layer higher than the top surface of the limiting layer is removed using a planarization process.

14. The method for forming a semiconductor structure according to claim 8, wherein:
after the second channel layer is formed, the sacrificial layer in the P-type region and an adjacent first channel layer on the sacrificial layer are configured to form a first channel deck, and the sacrificial layer in the N-type region and an adjacent second channel layer on the sacrificial layer are configured to form a second channel deck; and
the method for forming a semiconductor structure further comprises:
forming a first dummy gate structure spanning the first channel deck and a second dummy gate structure spanning the second channel deck after removing the limiting layer;
forming a first source/drain doped region in the first channel deck on two sides of the first dummy gate structure;
forming a second source/drain doped region in the second channel deck on two sides of the second dummy gate structure;
removing the first dummy gate structure to form a first gate opening, to expose the first channel deck;
removing the sacrificial layer exposed from the first gate opening to form a first groove, wherein the first groove is in communication with the first gate opening;
filling the first gate opening and the first groove with the first gate structure, so that the first gate structure surrounds the first channel layer;
removing the second dummy gate structure to form a second gate opening, to expose the second channel deck;
removing the sacrificial layer exposed from the second gate opening to form a second groove, wherein the second groove is in communication with the second gate opening; and
filling the second gate opening and the second groove with the second gate structure, so that the second gate structure surrounds the second channel layer.

15. The method for forming a semiconductor structure according to claim 8, wherein a partial thickness of the first channel layer in the N-type region is removed along the direction parallel to the substrate using an isotropic etching process.

16. The method for forming a semiconductor structure according to claim 8, wherein in the step of removing the partial thickness of the first channel layer in the N-type region along the direction parallel to the substrate, the first channel layer in the N-type region is removed by a thickness ranging from 1 nm to 10 nm.

17. The method for forming a semiconductor structure according to claim 8, wherein the remaining first channel layer in the N-type region is removed using an isotropic etching process.

18. The method for forming a semiconductor structure according to claim 8, wherein in the step of providing the base, a material of the first channel layer comprises silicon germanium, a material of the sacrificial layer comprises silicon germanium, and a mole percent of germanium in the material of the sacrificial layer is greater than a mole percent of germanium in the material of the first channel layer.

19. The method for forming a semiconductor structure according to claim 18, wherein in the step of providing the base, the mole percent of germanium in the material of the first channel layer ranges from 5% to 25%, and the mole percent of germanium in the material of the sacrificial layer ranges from 30% to 50%.

20. The method for forming a semiconductor structure according to claim 8, wherein in the step of providing the base, a material of the limiting layer is same as a material of the sacrificial layer.
